(19) United States
(12) Patent Application Publication
(10) Pub. No.: US 2012/0248587 A1
(43) Pub. Date: Oct. 4, 2012

(54) Miniature Microwave Component for Surface-Mounting

(75) Inventors: Pierre-Franck Alleaume, Orsay (FR); Claude Toussain, Orsay (FR)

(73) Assignee: UNITED MONOLITHIC SEMICONDUCTORS S.A, Orsay Cedex (FR)

(21) Appl. No.: 13/319,078

(22) PCT Filed: Apr. 22, 2010
(86) PCT No.: PCT/EP2010/055359

§ 371 Date: Jun. 18, 2012

(30) Foreign Application Priority Data
May 5, 2009 (FR) 0902160

(51) Int. Cl. H01L 23/522

(52) U.S. Cl. 257/664; 257/E23.142

(57) ABSTRACT

A miniature component includes an MMIC microwave chip encapsulated in an individual package for surface-mounting capable of operating at a frequency F0 very much higher than 45 GHz; and at least one contactless microwave port, by electromagnetic coupling, ensuring the transmission of coupling signals at a working frequency F0. The component comprises a passive multilayer integrated circuit having metallized layers and layers of dielectric material, a top face, a metallized bottom face, the metallized bottom face comprising, on the side of the contactless microwave port, an opening in the metallization for the passage of the coupling electromagnetic waves via the contactless microwave port and, between two layers of dielectric material, a metallized layer having at least one electromagnetic coupling electrical conductor connected to the electronic elements of the chip, said coupling electrical conductor being situated at the level of the contactless microwave port to ensure the transmission of microwave signals by electromagnetic coupling at the working frequency F0.

The invention relates to the electronic components that operate at millimetric frequencies and that have a contactless electromagnetic port.

These types of electronic components comprising at least one chip (or integrated circuit) operating at millimetric frequencies have applications notably in the field of radars for automobiles. In these types of applications, an electromagnetic wave is emitted at a millimetric frequency, the wave reflected by an obstacle is received by an antenna to extract from this wave distance information, on the one hand, and relative speed information, on the other hand, between this obstacle and the source which has emitted the wave. To this end, the vehicle is equipped with a system comprising radars positioned all around the vehicle making it possible to detect objects. Long range radars, operating for example at 77 GHz, are positioned at the front of the vehicle and short range radars, operating at 24 GHz and 79 GHz, are positioned at the rear and on the sides of the vehicle.

The relative speed and distance information is transmitted to a central unit of the system which ensures, for example, that the vehicle stays at a determined distance relative to the objects or relative to another mobile travelling on the same road.

The objective of these systems using radars for automobiles is firstly to provide a driving convenience with functions for servo controlling the speed of the vehicle relative to another vehicle in front of it, but also to signal potential dangers.

As a general rule, these systems using radars for automobiles include basic frequency generation and microwave emission and reception functions.

The components operating at millimetric frequencies can also be used for communication applications over short distances and at very high bit rates.

Whatever the application, the electronic processing of the millimetric frequency signals comprises a low-frequency processing part that can be implemented by silicon integrated circuits mounted on printed circuits. This part can be produced by very widely used and inexpensive technologies, with simple connections to be produced between circuit elements on one and the same integrated circuit chip or between different integrated circuit chips. The processing also comprises a very high frequency part (above 45 GHz), that can be implemented only by components and integrated circuits made of semiconductive materials suited to the microwave frequencies (notably gallium arsenide GaAs and its derivatives, or even SiGe). These integrated circuits are called MMIC, standing for “microwave monolithic integrated circuits”. This very high frequency part raises production problems and generally proves costly.

For relatively complex functions, components are produced encapsulated in a metallic package containing a large number of MMIC chips, the quantity of circuit elements that can be placed in one and the same chip being far more limited for the MMIC circuits than for the silicon low-frequency circuits. These chips are mounted on a substrate comprising interconnects that are difficult to produce and therefore costly given the very high frequencies at which they work.

The mounting of the chips on a hybrid substrate (mounting usually with wiring to link the chips to the hybrid substrate) is in itself very costly when there are a lot of chips.

These components comprise, notably in the case of applications for automobiles, contactless ports by electromagnetic coupling for the emission and reception of the waves.

The transmission by electromagnetic coupling at these very high frequencies is handled by using the guided propagation properties of the electromagnetic signals inside the package and above all between the interior and the exterior. This package notably comprises a conductive cover (metallic or metallized cover) which seals the lines of propagation of the signals coming from the chip or going to the chip. The conductive cover is situated above the contactless external port, at a distance such that it constitutes (at the main working frequency for which the component is designed) an electromagnetic short circuit favoring the signal transmission by free propagation via this port.

The ports at the working frequency F0 are transitions by electromagnetic coupling in air (or in a gas or in a vacuum or even in any low-loss dielectric material), and notably conductive elements capable of radiating toward a waveguide placed facing these elements, or capable of receiving an electromagnetic radiation output from a waveguide in front of which they are placed. The package in which the MMIC chips are sealed comprises a nonconductive part facing these conductive elements so as to allow the electromagnetic energy to pass between the guide and the conductive elements.

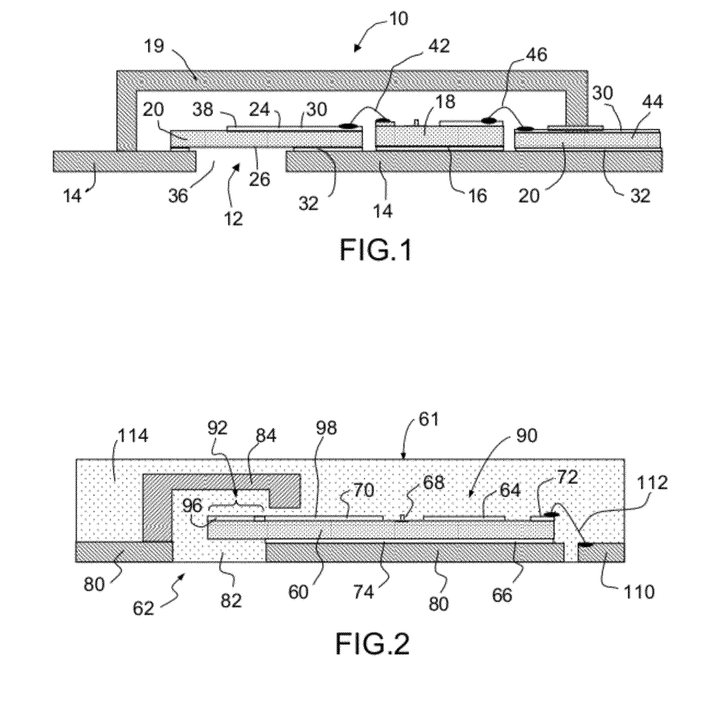

FIG. 1 represents a microwave component of the prior art for automobile applications described in the French patent number 02 14684.

The component of FIG. 1 is encapsulated in a package 10 having a contactless electromagnetic port 12 and comprises a metallic base 14, serving as substrate on which is directly mounted, by its rear face 16, an MMIC microwave chip 18, a double-sided ceramic substrate 20 used for the interconnects inside the package and toward the exterior of the package, and a metallic or metallized cover 19 covering the base to seal, between the base and the cover, the chip and the ceramic substrate 20. The MMIC chip 18 is soldered or bonded directly onto the base 14.

The ceramic substrate 20 is preferably a substrate that is metallized on both its faces 24, 26 comprising metallizations 30 on its front face 24 to constitute transmission lines, metallizations 32 on its rear face 26 to constitute a ground plane.

The dimensions of the different dielectric and conductive parts are such that the component correctly operates at the working frequency concerned F0 (77 GHz). The metallizations 30 and 32 serve on the one hand to establish interconnects between chips and on the other hand to establish external ports for the package.

The contactless electromagnetic port 12 of the component of FIG. 1 comprises a transition by electromagnetic coupling that allows the contactless signal at the frequency of 77 GHz to pass from a waveguide to the MMIC chip 18, or vice versa.

This transition by electromagnetic coupling preferably takes place via an opening 36 in the package 10, and more specifically in the metallic base 14.

The substrate 20 comprises a radiating element 38 communicating, for example, with a waveguide placed in front of the opening 36, the radiating element acting as element for receiving and emitting an electromagnetic wave entering or leaving the package.

The electrical links between the substrate 20 and the chip 18 are produced by wiring.

The component includes other ports 44 operating at frequencies lower than those of the microwave port. The MMIC chip is also linked to these other ports 44 by wiring 46.

The component is connected with another similar component or with a different component mounted on a conventional printed circuit by the other ports 44.

FIGS. 2a and 2b respectively represent a cross-sectional view and a plan view of another embodiment of a miniaturized microwave component for surface-mounting described in the French patent number 04 13583.

The component of FIGS. 2a and 2b comprises an MMIC chip 60 encapsulated in a package 61 having a port 62 by contactless electromagnetic coupling.

The MMIC chip 60 comprises an active face 64 and a rear face 66, opposite the active face; the two faces 64, 66 are metallized. The active face 64 comprises electronic components 68 and electrical conductors 70, 72 of the active face. The rear face 66 comprises electrical conductors of the rear face and, among these conductors of the rear face, a conductor forming a ground plane 74.

The package 61 comprises a metallic base 80 serving as substrate on which is directly mounted the MMIC chip 60 by its rear face 66, the base having an opening 82 for the passage of the electromagnetic waves received or emitted by the integrated circuit forming, with a metallic cover 84 mounted on the metallic base, the port 62 by contactless electromagnetic coupling.

The MMIC chip 60 comprises, on the side of one of its ends, an area for mounting 90 on the metallic base 80 of the package and, on the side of another end opposite the first, an electromagnetic transition area 92 at the level of the port 62 by electromagnetic coupling, for example with a waveguide. The rear face 66 of the chip, at the level of the transition area 92, does not include any metallization to allow the passage of the electromagnetic waves via the contactless port 62.

The transition area 92 of the chip comprises, preferably on the active face 64, a coupling electrical conductor 96 linked to a microstrip line 98 of the chip formed by a conductor of the active face and the ground plane 74 of the rear face.

The electromagnetic port 62 of the package ensures a contactless transition of the microwave signals between the component and a waveguide coupled to the component.

The contactless port 62 is formed, in this example of FIGS. 2a and 2b, by the metallic cover 84 and the opening 82 in the metallic base forming a waveguide at the working frequency F0 of emission/reception of the integrated circuit 60.

The dimensions of the different dielectric and conductive parts of the package are such that the component correctly operates at the working frequency F0 concerned (77 GHz).

The package comprises, on the side of the metallic base 80, in addition to the ground electrical conductor 82, electrical pads 110 for interconnecting the integrated circuit with other electronic components via an interconnect substrate.

The electrical conductors 72 of the active face of the chip, for other chip ports, are linked by connection wires 112 to the electrical pads of the package. These other contact-based ports are intended for transmission to the chip: of the signals at the sub-harmonic frequencies of the working frequency F0 (77 GHz), of the control signals, the power supplies.

The package is sealed by a molding 114 of dielectric material covering the active surface of the integrated circuit and revealing the mounting surface of the package comprising the mounting electrical pads.

Preferably, the dielectric material fills the contactless electromagnetic port 62 of the package, but, in other implementations, the space between the cover and the metallic base may contain a gas surrounding the component, for example air.

In the microwave systems, and notably in the case of applications for automobile radars, the increasing number of functionalities of such systems involves the use of an increasingly high number of detection radars around the vehicle which necessitates a greater effort to reduce the costs of the individual functions of the system.

One of the major problems for these automobile applications is the cost of the emission/reception millimetric module. This cost results from the components used but also from the assembly technology used to fabricate these modules and the method for assembling the component within the system.

The existing solutions do not make it possible to achieve the market-related cost objectives. These solutions are limited for two essential reasons, the implementation cost (equipment, learning, reproducibility), the component production cost.

The invention makes it possible to reduce the production costs of the microwave components with contactless ports by electromagnetic coupling by proposing a microwave miniature component comprising: an MMIC microwave chip encapsulated in an individual package for surface-mounting, the chip having an active face comprising electronic elements and electrical conductors of the active face and a rear face opposite the active face, at least one contactless microwave port, by electromagnetic coupling, for the communication of electrical signals between the interior and the exterior of the package comprising an opening that is transparent to the electromagnetic waves ensuring the transmission of coupling signals at a working frequency F0, characterized in that it comprises a passive multilayer integrated circuit having metallized layers and layers of dielectric material, a top face, a metallized bottom face, the metallized bottom face comprising, on the side of the contactless microwave port, an opening in the metallization for the passage of the coupling electromagnetic waves by the contactless microwave port and, between two layers of dielectric material, a metallized layer having at least one electromagnetic coupling electrical conductor connected to the electronic elements of the chip, said coupling electrical conductor being situated facing the contactless microwave port to ensure the transmission of microwave signals by electromagnetic coupling at the working frequency F0.

Advantageously, the component comprises a contact-based microwave port with a frequency lower than the working frequency F0.

In one embodiment, the frequency lower than the working frequency of the contact-based microwave port is a sub-harmonic frequency F0/n of the working frequency F0, n being a number greater than or equal to 2.

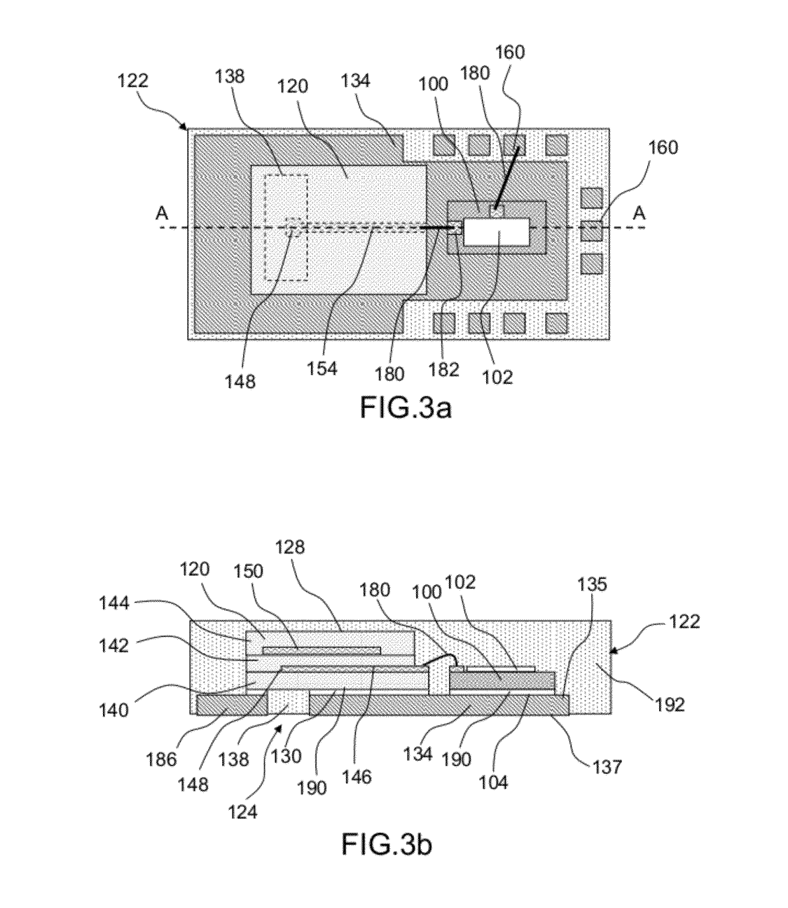

In another embodiment, the component comprises a metallic base having an internal face, an external face, an opening in the base forming the contactless microwave port, the microwave chip and the passive multilayer integrated circuit being mounted on the internal face of said metallic base (FIG. 3, 4, 7, 8).

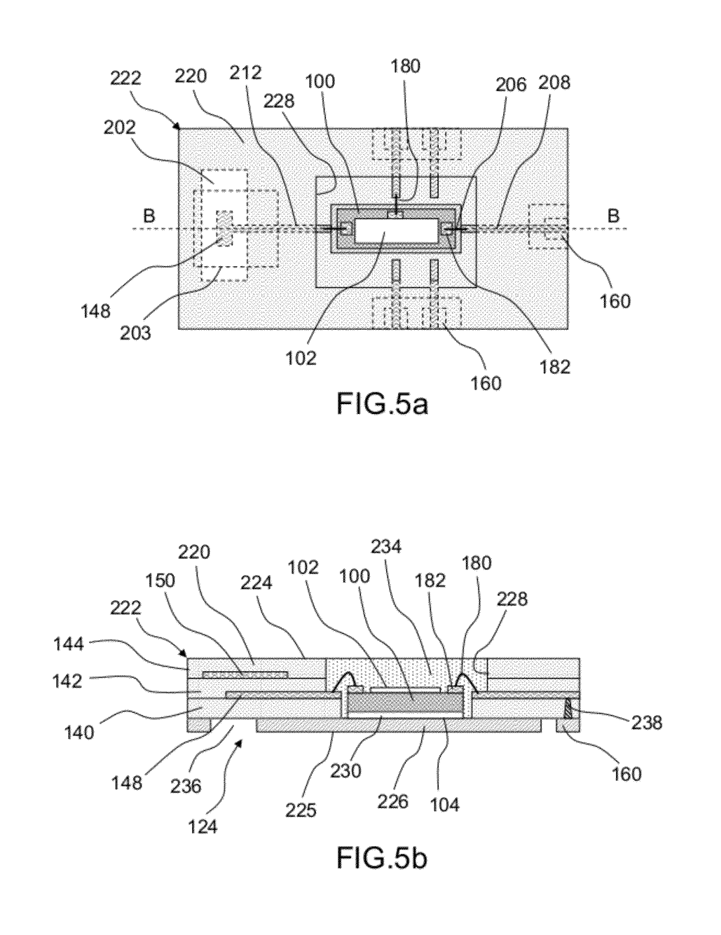

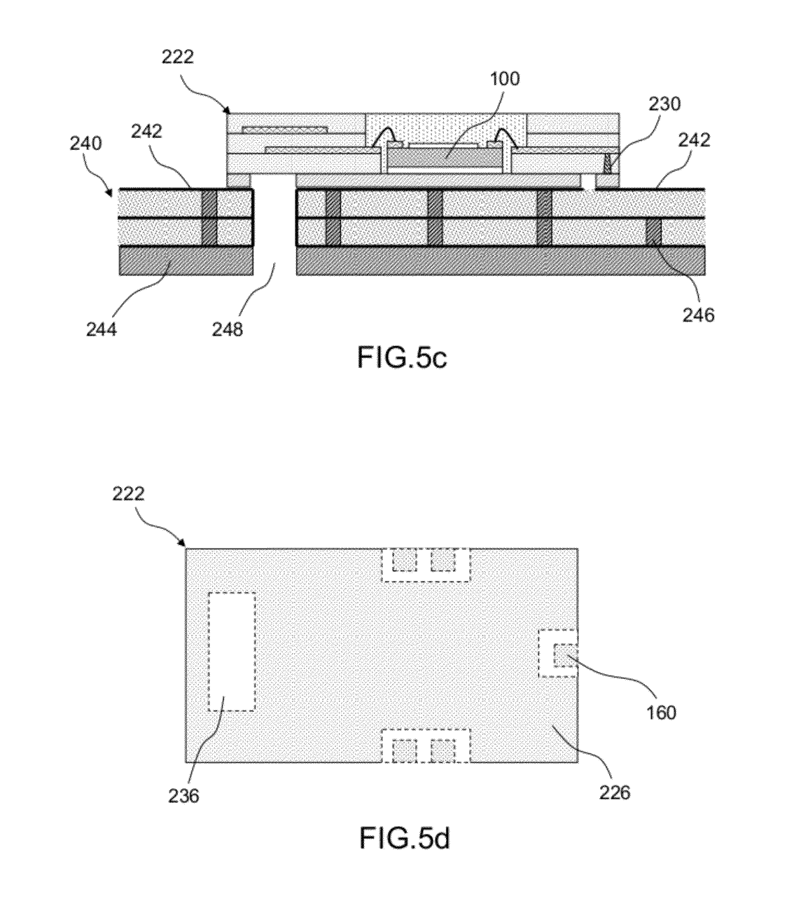

In another embodiment, the metallization of the bottom face of the multilayer integrated circuit forms a ground plane of the package (FIG. 5, 6).

In another embodiment, the multilayer integrated circuit comprises a cavity in its central part revealing the metallization of its bottom face, the chip, housed in the cavity of the passive multilayer integrated circuit being mounted, by its rear face, on the metallization of the bottom face of said multilayer integrated circuit (FIG. 5).

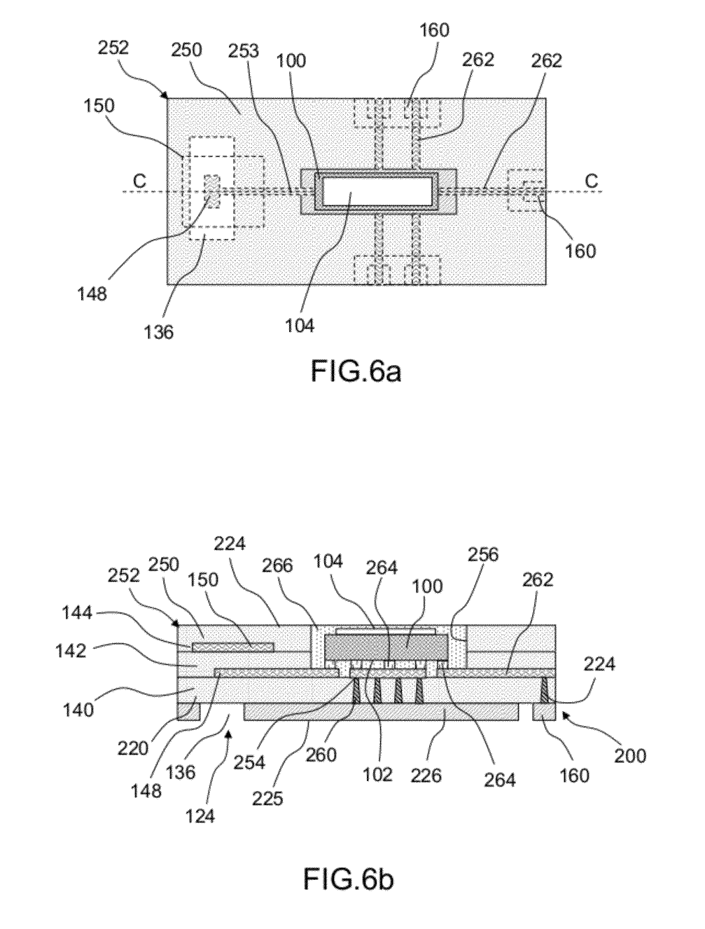

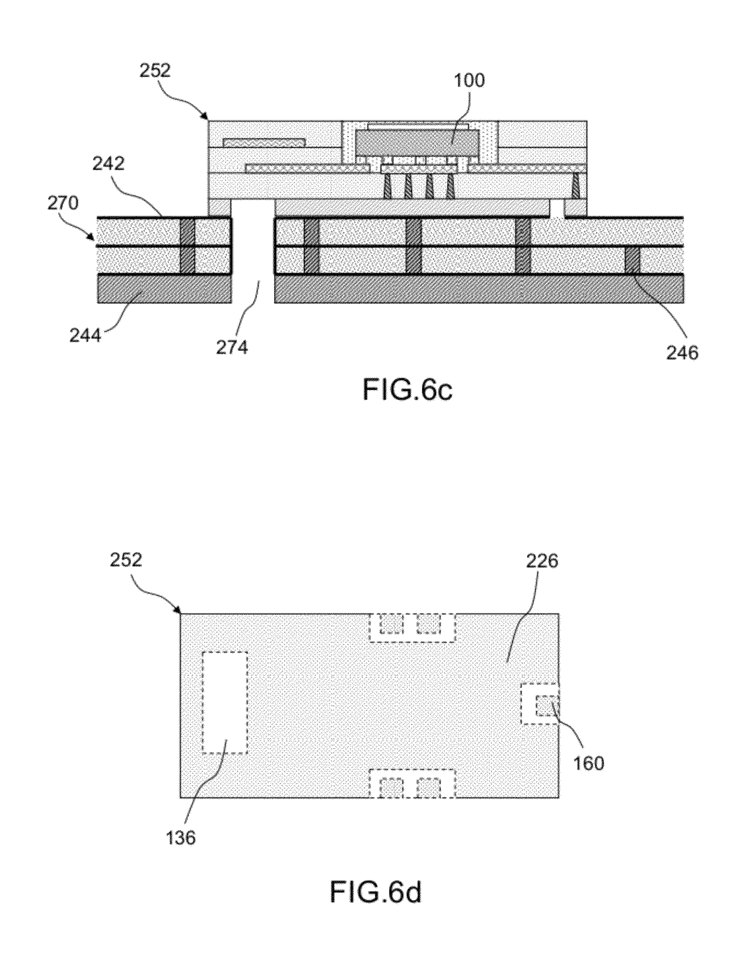

In another embodiment, the passive multilayer integrated circuit comprises, between a first and a second layer of dielectric material, in addition to the coupling electrical conductor, electrical conductors for mounting the chip on the multilayer passive integrated circuit, a cavity in the central part of the passive multilayer integrated circuit revealing said electrical conductors for mounting the chip (FIG. 6).

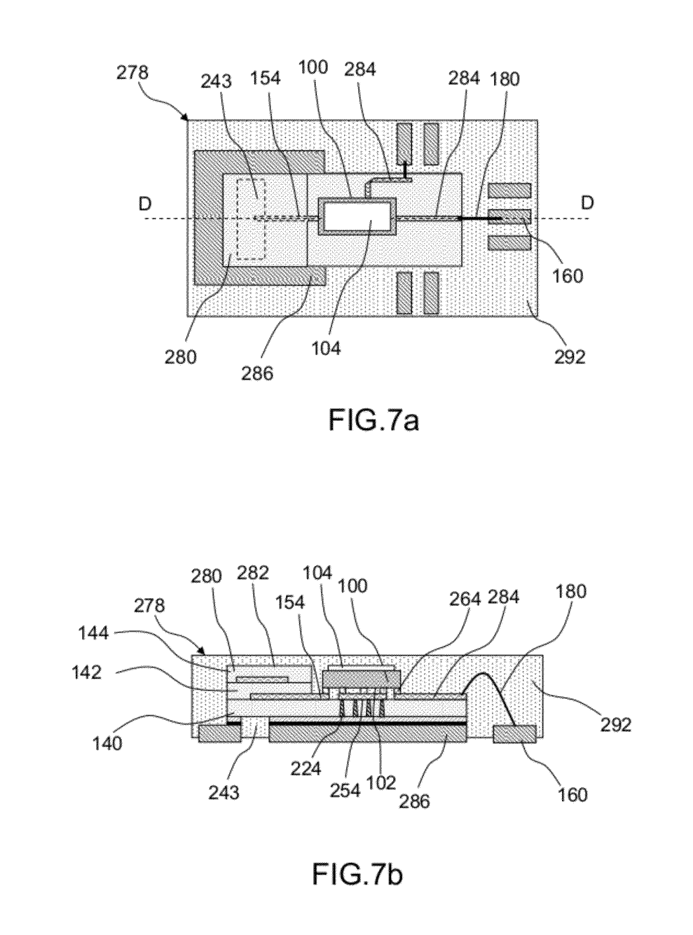

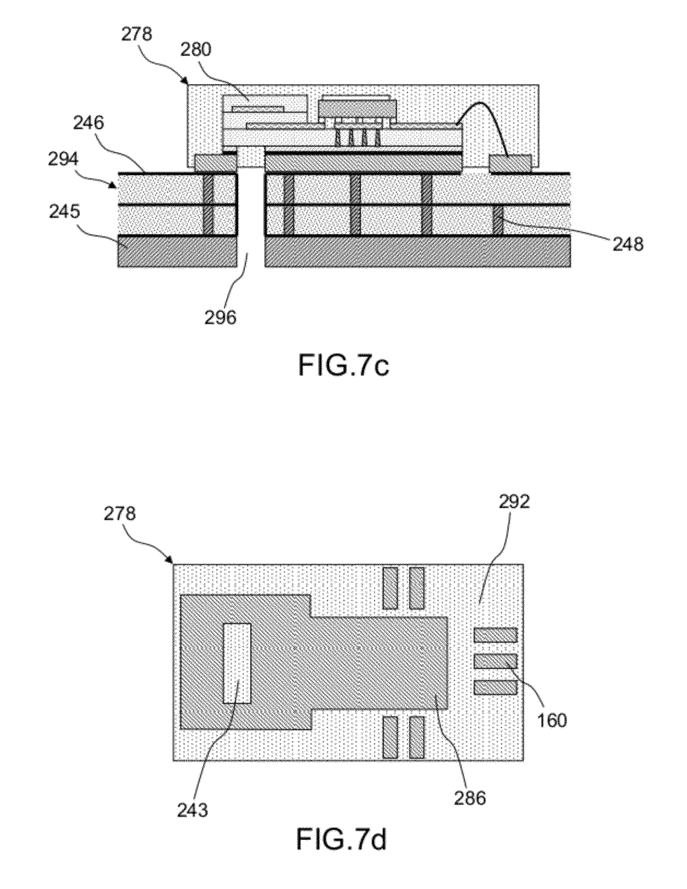

In another embodiment, the passive multilayer integrated circuit comprises, between a first and a second layer of dielectric material, in addition to the coupling electrical conductor, electrical conductors for mounting the chip, the second and a third layer of dielectric material partially covering, on the side of the opening in the metallization of the bottom face of the multilayer integrated circuit, the first layer of dielectric material revealing the electrical conductors for mounting the chip on said first layer of dielectric material (FIG. 7, 8).

In another embodiment, the multilayer integrated circuit comprises, between the bottom face and the top face, a first, a second and a third layer of dielectric material, between the first and the second layers of dielectric material, a first metallic layer comprising at least the electromagnetic coupling electrical conductor, between the second and the third layer of dielectric material at the level of the opening of the metallization of the bottom face of the multilayer integrated circuit, another metallic layer forming a reflective plane for the electromagnetic waves in the contactless microwave port (FIG. 3, 4, 5, 6, 7, 8).

In another embodiment, an electromagnetic coupling electrical conductor and a ground plane of the passive multilayer integrated circuit form a slot antenna favoring the transmission of the working frequency through the contactless microwave port.

In another embodiment, the coupling electrical conductor is electrically linked to the chip by a microstrip line formed by an electrical conductor of the metallic layer comprising the coupling electrical conductor and the metallized bottom face of the multilayer integrated circuit.

In another embodiment, the chip MMIC and the multilayer integrated circuit are protected by a coating resin sealing the package of the component.

In another embodiment, the chip (MMIC) 100 is interconnected to the multilayer integrated circuit by electrical conductor wires.

In another embodiment, the chip (MMIC) 100 is interconnected to the multilayer integrated circuit by metallic pads.

One main objective of the microwave component according to the invention is to reduce the fabrication cost of microwave systems and simplify their fabrication.

A second objective is to be able to use a microwave component fabrication technology very similar to the technologies currently implemented for high volume fabrications, for example, those used for plastic packaged components. For this, collective assembly methods, in particular in the chip mounting and wiring and package sealing steps are used.

Another objective of the component is its compatibility with the surface-mounting techniques, which represents a major asset for applications at such millimetric frequencies.

In the component according to the invention, the coupling electrical conductor at the level of the contactless port serves as electromagnetic sensor coupled with a waveguide external to the package.

For certain applications of the microwave component according to the invention, the package preferably comprises, in addition to a contactless port capable of effective electromagnetic coupling at above 45 GHz (at least up to 120 GHz), a contact-based port incapable of working effectively at a frequency Fc above 45 GHz but designed to work at at least this frequency Fc lower than the working frequency. This frequency Fc could be, for certain applications, a sub-harmonic frequency F0/n of the working frequency F0. In the latter case, the microwave component will preferably include frequency multiplication means necessary for converting the sub-harmonic frequency Fc=F0/n to the working frequency F0.

The port incapable of working at 77 GHz but capable of working up to 40 GHz or a little above, is linked to the chip by electrical conductor wire or metallic pad through microstrip or coplanar propagation lines.

In the case of the lower frequency signals (F0/n), the connection of the microwave miniature component with other components placed on one and the same substrate will be easy because the frequencies conveyed are much lower. Transmission lines linking the contact pads of the different components will be able to be produced on the mounting substrate.

Other features and advantages of the invention will become apparent from reading the following detailed description which is given with reference to the appended drawings in which:

FIG. 1, already described, represents a microwave component of the prior art;

FIG. 2, already described, represents another microwave component of the prior art;

FIGS. 3a and 3b respectively represent a plan view and a cross-sectional view of a first embodiment of the microwave component according to the invention;

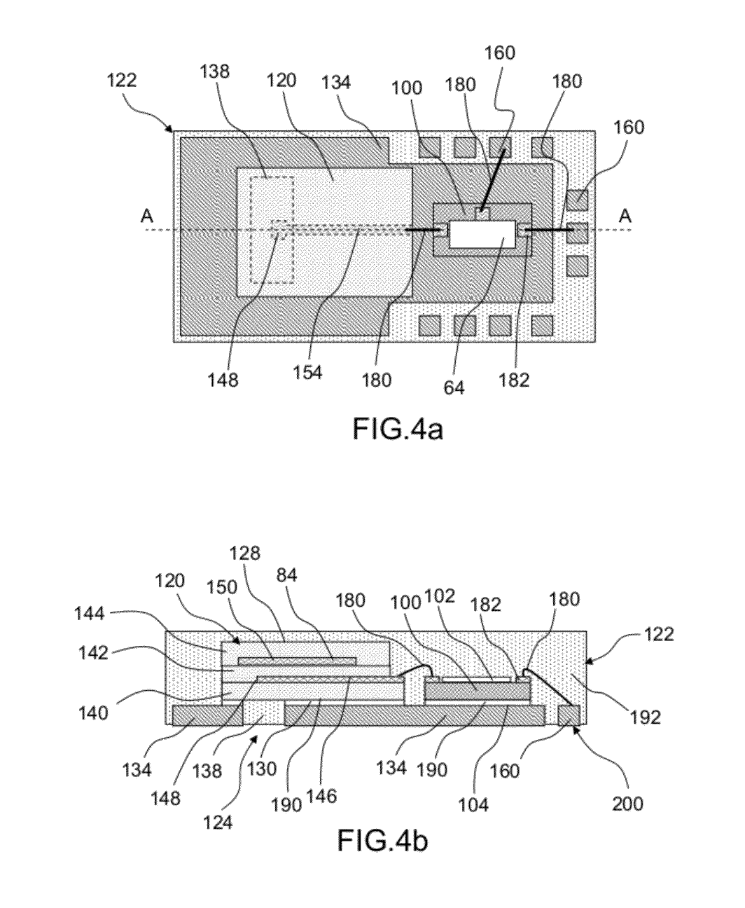

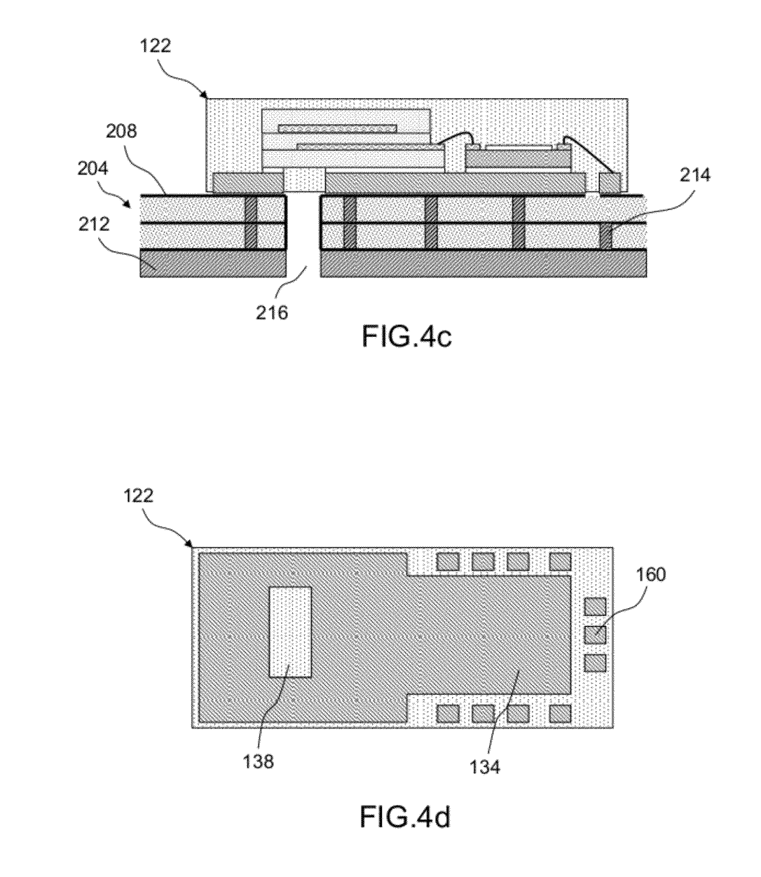

FIGS. 4a and 4b represent a variant of the component of FIGS. 3a and 3b;

FIGS. 4c and 4d show the component of FIG. 4a mounted on a printed circuit;

FIGS. 5a and 5b represent an alternative of the component of FIGS. 4a and 4b;

FIGS. 5c and 5d show the component of FIG. 5a mounted on a printed circuit;

FIGS. 6a and 6b represent a variant of the component of FIGS. 5a and 5b;

FIGS. 6c and 6d represent the microwave component of FIGS. 6a and 6b assembled on a printed circuit card by a surface-mounting technique;

FIGS. 7a and 7b represent a development of the component represented by FIGS. 6a and 6b comprising a metallic base under the passive multilayer integrated circuit as represented in FIGS. 4a and 4b;

FIGS. 7c and 7d represent the microwave component of FIGS. 7a and 7b assembled on a printed circuit card; and

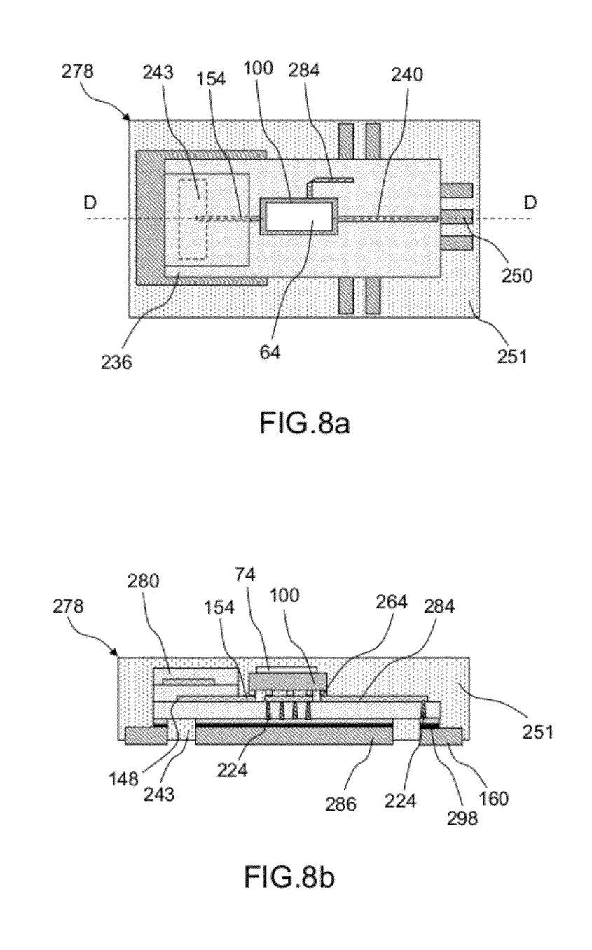

FIGS. 8a and 8b represent a development of the component represented in FIGS. 7a and 7b.

The component according to the invention, represented by FIGS. 3a and 3b, comprises a microwave chip (MMIC) 100, such as that used for the prior art package embodiments of FIG. 1, having an active face 102 comprising active elements and a rear face 104 of the chip and, according to a main characteristic of the component according to the invention, a passive multilayer integrated circuit 120 forming an electromagnetic coupling element for coupling the component with the external environment.

The passive multilayer integrated circuit 120 and the chip 100 are encapsulated in a plastic package 122 including a contactless microwave port 124 by electromagnetic coupling intended to operate at a working frequency F0.

The component of FIG. 3a comprises a metallic base 134 having an internal face 135 and an external face 137 for mounting the component on a printed circuit. The metallic base 134 includes an opening 138 forming the contactless microwave port 124 of the microwave component.

The passive multilayer integrated circuit 120 has a top face 128 and a bottom face 130 and, between the bottom face 130 and the top face 128, a first 140, a second 142 and a third 144 layer of dielectric material.

The microwave chip 100 and the passive multilayer integrated circuit 120 are mounted, the chip by its rear face 104 and the multilayer integrated circuit by its bottom face 130, on the internal face 135 of the metallic base 134 of the microwave component.

The passive multilayer integrated circuit 120 also comprises metallic layers, a first metallic layer 146, between the first 140 and the second 142 layer of dielectric material, comprising at least one electromagnetic coupling electrical conductor 148, for ensuring the transmission of microwave signals by electromagnetic coupling at the working frequency F0 and, between the second 142 and the third 144 layer of dielectric material, another metallic layer 150 forming a reflective plane for the electromagnetic waves in the contactless microwave port 124.

The electromagnetic coupling electrical conductor 148 is connected to the electronic elements of the chip 100 via a microstrip line 154 formed by a ground plane of the bottom face 130 of the passive multilayer circuit 120 and a strip-form connection electrical conductor of the first metallic layer 146.

The coupling electrical conductor 148 of the passive multilayer integrated circuit 120 provides for the excitation of a waveguide at the opening 136 of the metallic base 134 of the component.

The microwave chip (MMIC) 100 is linked, on the one hand, to low-frequency ports of the package 122 in the form of mounting metallic pads 160 of the component and, on the other hand, to the microstrip line 154 of the multilayer integrated circuit 120 connected to the coupling electrical conductor 148, via electrical conductor wires 180 soldered to metallic pads 182 of the chip 100.

The passive multilayer integrated circuit 120 and the chip 100 are mounted on the internal face 135 of the metallic base 134 by means of a bonding layer 190.

The microwave component is covered with a coating resin 192 ensuring the final mechanical protection of the component and its encapsulation in the form of the package 122.

The chip 100 in this embodiment can handle different functions of an automobile radar such as the reception and emission, the generation of local and mixing oscillators to supply an intermediate frequency IF. The metallic pads 160 convey, in this case, low frequencies.

FIGS. 4a and 4b represent a variant of the component of FIGS. 3a and 3b.

In this variant of FIGS. 4a and 4b, the package 122 includes another microwave port 200 by contact with a printed circuit for mounting the component using volume production fabrication technologies. The microwave port with contact 200, in the form of metallic pads 160 of the package, is incapable of working at the working frequency F0 but capable of working at a sub-harmonic frequency F0/n of the working frequency F0.

In the same way as in the embodiment of FIGS. 3a and 3b, a microwave port of the chip 100 is linked to the port 200 of the package, capable of working at F0/n, by an electrical conductor wire 180.

The components of FIGS. 3a, 3b, 4a, 4b can then be assembled on a printed circuit card 204 by a surface-mounting technique.

FIGS. 4c and 4d show the component of FIG. 4a mounted on a printed circuit by surface-mounting techniques.

The printed circuit card 204 incorporates various conductors 208, 212 for routing the electrical signals to the package 122. The conductors 208 and the ground returns 212 are interconnected by metallized holes 214.

The electromagnetic signal at the frequency F0 is coupled to a waveguide by an opening 216 through the printed circuit card 204 from the coupling conductor 148 incorporated in the microwave component of FIG. 4a.

The footprint of the package 122 of the component mounted on the printed circuit 204 is represented in FIG. 4d.

FIGS. 5a and 5b represent an alternative of the component of FIGS. 4a and 4b.

In the case of the component of FIGS. 5a and 5b, a passive multilayer integrated circuit 220 is encapsulated in a microwave package 222 including the contactless microwave port 124 by electromagnetic coupling intended to operate at the working frequency F0.

The passive multilayer integrated circuit 222 comprises three layers of dielectric material, the first 140, the second 142 and the third 144 layers, a top face 224 and a bottom face 225 of the multilayer integrated circuit comprising a metallization 226 of sufficient thickness to form a ground plane.

The passive multilayer integrated circuit 220 of the component of FIGS. 5a and 5b also comprises a cavity 228 in its central part revealing the metallization 226 of its rear face 225.

The chip 100, housed in the cavity 228 of the passive multilayer integrated circuit 220, is mounted, by its rear face 104, on the metallization 226 of the bottom face 225 of said multilayer integrated circuit 220.

The metallization 226 of the bottom face 225 of the passive multilayer integrated circuit 220 serves, in this embodiment, as metallic base for the microwave component for its surface-mounting on a printed circuit.

As in the embodiment of FIGS. 3a and 3b, the multilayer integrated circuit 220 comprises, on the side of the contactless microwave port 124, between the first 140 and the second 142 layer of dielectric material, the coupling electrical conductor 148 and, between the second 142 and the third 144 layer, the other metallic layer 150 forming a reflective plane for the electromagnetic waves in the contactless microwave port 124.

The chip 100 is mounted on the metallization 226 of the passive multilayer integrated circuit by a bonding layer 230.

The electrical conductors of the active face 102 of the chip 100 are linked by electrical wires 180 to the electrical conductors of the passive multilayer integrated circuit 220 and to the electrical pads 182 of the chip.

The cavity 228 of the multilayer integrated circuit 220, in which the chip 100 is placed, is sealed by a protective resin 234.

The metallization 226 forming the ground plane of the passive multilayer integrated circuit 220 includes an opening 236 at the level of the contactless port 124 of the component allowing for the passage of the electromagnetic waves and, consequently, an electromagnetic coupling at the working frequency F0 to an external system.

The external face for mounting the component of FIGS. 5a and 5b on a printed circuit also incorporates the metallic pads 160 enabling the component to be connected to the external system at the low frequencies.

The connection between these pads 160 and the electrical conductors of the passive multilayer integrated circuit 220 is made by means of metallized holes 238.

FIGS. 5c and 5d show the component of FIGS. 5a and 5b mounted by a surface-assembly technique on a printed circuit card 240 incorporating different conductors 242 that can be inter-linked or linked to a ground 244 of the printed circuit 240 by metallized holes 246.

The working signal at the frequency F0 is coupled to a waveguide via the coupling conductor 148 of the component mounted on the printed circuit through an opening 248 in said printed circuit.

FIG. 5d represents the footprint of the component of FIGS. 5a and 5b as it appears on the printed circuit 240.

FIGS. 6a and 6b represent a variant of the component of FIGS. 5a and 5b.

FIGS. 6a and 6b represent a component that has two microwave ports, the contactless port 124 and the port with contact 200.

In the case of the embodiment of FIGS. 6a and 6b, a passive multilayer integrated circuit 250 such as that of the embodiment of FIGS. 5a and 5b encapsulated in a package 252 comprises three layers of dielectric material, the first 140, the second 142 and the third 144 layers, the top face 224 and the bottom face 225 of the multilayer integrated circuit 250 comprising the metallization 226 of sufficient thickness to form a ground plane.

The passive multilayer integrated circuit 250 comprises, between the first 140 and the second 142 layers of dielectric material, in addition to the coupling electrical conductor 148, electrical conductors 254 for mounting the chip 100 by its active face 102.

A cavity 256 in the central part of the passive multilayer integrated circuit 250 reveals said electrical conductors 254 for mounting the chip 100 on the passive multilayer integrated circuit 250. The passive multilayer integrated circuit 250 comprises metallized holes 260, 224 linking the electrical conductors 254, 262 for mounting the chip on the passive multilayer integrated circuit 250 to the mounting electrical conductors 160 of the microwave component via electrical conductors 262 of the passive multilayer integrated circuit.

The chip 100, housed in the cavity 256 of the passive multilayer integrated circuit 250, is mounted by its rear face 102 on the mounting electrical conductors 254 of the chip, by metallic pads 264. These metallic pads 264 ensure the electrical and mechanical connection of the chip 100 to the passive multilayer integrated circuit 250.

In a variant embodiment of FIGS. 6a and 6b, not represented in the figures, the chip 100 can be mounted by its active face 104 on the mounting electrical conductors 254, 262 of the chip. This configuration is commonly called “flip-chip”. The active face 104 of the chip 100 then directly faces the electrical conductors 254 for mounting the chip 100 produced in the cavity 256 of the passive multilayer integrated circuit 252. The link between the conductors of the chip 100 and the mounting electrical conductors 254, 262 of the chip 100 being made by the metallic pads 264.

The metallization 226 forming the ground plane of the bottom face 224 of the passive integrated circuit 250 serves, as in the embodiment of FIGS. 5a and 5b, as base for the component for its surface-mounting on a printed circuit.

The coupling electrical conductor 148 is thus linked to the microwave port of the chip 100 operating with the signal of the working frequency F0 with an electrical length much shorter than in the case of a connection by electrical conductor wire. This favors the operation of the component at very high frequencies F0.

Similarly, the contact-based port 200 by the mounting metallic pad 160 of the microwave component is linked without electrical wire to the chip 100, which favors the operation of this port at frequencies much higher than in the case of the low-frequency port by the metallic pad 160 described in FIG. 5b.

The metallization 226 of the multilayer integrated circuit 250 also includes the opening 136 allowing for the transmission of the signal at the working frequency F0 to the external system.

The MMIC chip 100 is protected by a coating resin 266 sealing the package of the component.

FIGS. 6c and 6d represent the microwave component of FIGS. 6a and 6b assembled on a printed circuit card 270 by a surface-mounting technique.

This card 270 incorporates in particular a waveguide opening 274. FIG. 6d represents the footprint of the component of FIGS. 6a and 6b as it appears on the printed circuit 270.

FIGS. 7a and 7b represent a development of the component represented by FIGS. 6a and 6b comprising a metallic base under the passive multilayer integrated circuit as represented in FIGS. 4a and 4b.

In the case of the embodiment of FIGS. 7a and 7b, a package 278 comprises a passive multilayer integrated circuit 280 comprising three layers of dielectric material, the first 140, the second 142 and the third 144 layers, a top face 282 and a metallized bottom face 284. The multilayer integrated circuit 280 is mounted on a metallic base 286.

The multilayer integrated circuit 280 comprises, between the first 140 and the second 142 layer of dielectric material, in addition to the coupling electrical conductor 148, the electrical conductors 254 for mounting the chip 100 by its active face 102 such as those of the embodiment of FIGS. 6a and 6b.

The second 142 and third 144 layers of dielectric material partially cover, on the side of the contactless port 124 of the component, the first layer 140 of dielectric material revealing the electrical conductors 254 for mounting the chip 100 on said first layer 140 of dielectric material.

This embodiment of FIGS. 7a and 7b makes it possible to reduce and simplify the definition of the bottom face of the passive multilayer integrated circuit 280.

The connections of the MMIC chip 100 mounted on the multilayer integrated circuit 280 comprising low-frequency electrical conductors 284 and the contactless coupling electrical conductor 148 are made through metallic pads 264 so as to increase the maximum frequency F0 of the component.

The contactless port, for coupling the component at the frequency F0 to the external system, is produced by an opening 243 in the metallic base 286 of the microwave component and an opening 136 opposite in the metallization of the bottom face of the passive multilayer integrated circuit 280 allowing for an electromagnetic coupling with the exterior of the component by the integrated coupling conductor 148.

As for the other embodiments, the low-frequency signals are injected to the component by port pads 160 produced on the metallic base 286. These port pads 160 are linked to the electrical conductors of the passive multilayer integrated circuit by electrical conductor wires 180.

The component of FIGS. 7a and 7b is encapsulated by a coating of a protection resin 292.

In a variant embodiment of FIGS. 7a and 7b, not represented in the figures, the chip 100 can be mounted by its active face 104 on the mounting electrical conductors 254 of the chip. This configuration is commonly called “flip-chip”. The active face 104 of the chip 100 then directly faces the mounting conductors 254, 284 of the chip produced on the multilayer passive integrated circuit 280. The link between the conductors of the chip 100 and the chip mounting conductors 254 being made by the metallic pads 264.

FIGS. 7c and 7d represent the microwave component of FIGS. 7a and 7b assembled on a printed circuit card.

FIG. 7c represents the assembly of the component of FIGS. 7a and 7b on a printed circuit card 294 incorporating in particular, as in the other cases, an opening 296 for coupling to an external system, at the working frequency F0.

FIG. 7c represents the footprint of the component of FIGS. 7a and 7b as it appears on the printed circuit 294.

FIGS. 8a and 8b represent a development of the component represented in FIGS. 7a and 7b.

The component of FIGS. 8a and 8b is identical in all respects to that of FIGS. 7a and 7b, except that the connection of the passive multilayer integrated circuit 280 to the metallic base 286 is made by bonding or hard soldering 298 at the level of the low-frequency connections 160 of the package. This makes it possible to eliminate the wiring wires 180 shown in FIGS. 7a and 7b, making it possible to increase the maximum frequency of the low-frequency port via the component mounting pads 160.

Among the main advantages of the microwave component according to the invention the following can be cited: the microwave component is compatible with the surface-mounting (SMC) techniques, including for applications beyond 45 GHz; the use of inexpensive materials for the production of the printed circuit on which the microwave component will be mounted despite the management of frequencies very much higher than 45 GHz; the elimination of the lead and wire-type connections at the millimetric working frequency F0; use of the collective fabrication technologies for the microwave packages. This makes it possible to significantly reduce the production cost of the microwave component.

These main advantages of the miniature component according to the invention culminate in a significant reduction in the cost of fabrication of microwave systems and reproducibility of the performance levels.

1. A microwave component comprising:
an MMIC microwave chip encapsulated in an individual package for surface-mounting, the chip having an active face comprising electronic elements and electrical conductors of the active face (30, 70, 72) and a rear face opposite the active face,
at least one contactless microwave port, by electromagnetic coupling, for the communication of electrical signals between the interior and the exterior of the package comprising an opening that is transparent to the electromagnetic waves ensuring the transmission of coupling signals at a working frequency F0,
a passive multilayer integrated circuit having metallized layers and layers of dielectric material, a top face, a metallized bottom face, the metallized bottom face comprising, on the side of the contactless microwave port, an opening in the metallization for the passage of the coupling electromagnetic waves by the contactless microwave port and, between two layers of dielectric material, a metallized layer having at least one electromagnetic coupling electrical conductor connected to the electronic elements of the chip, said coupling electrical conductor being situated facing the contactless microwave port to ensure the transmission of microwave signals by electromagnetic coupling at the working frequency F0.

2. The microwave component as claimed in claim 1, further comprising a contact-based microwave port with a frequency (Fc) lower than the working frequency F0.

3. The microwave component as claimed in claim 2, wherein the frequency (Fc) lower than the working frequency of the contact-based microwave port is a sub-harmonic frequency F0/n of the working frequency F0, n being a number greater than or equal to 2.

4. The microwave component as claimed in claim 1, further comprising a metallic base having an internal face, an external face, an opening in the base forming the contactless microwave port, the microwave chip and the passive multilayer integrated circuit being mounted on the internal face of said metallic base.

5. The microwave component as claimed in claim 1, wherein the metallization of the bottom face of the multilayer integrated circuit forms a ground plane of the package.

6. The microwave component as claimed in claim 1, wherein the multilayer integrated circuit comprises a cavity in its central part revealing the metallization of its bottom face, the chip, housed in the cavity of the passive multilayer integrated circuit being mounted, by its rear face, on the metallization of the bottom face of said multilayer integrated circuit.

7. The microwave component as claimed in claim 1, wherein the passive multilayer integrated circuit comprises, between a first and a second layer of dielectric material, in addition to the coupling electrical conductor, electrical conductors for mounting the chip on the passive multilayer integrated circuit, a cavity in the central part of the passive multilayer integrated circuit revealing said electrical conductors for mounting the chip.

8. The microwave component as claimed in claim 1, wherein the passive multilayer integrated circuit comprises, between a first and a second layer of dielectric material, in addition to the coupling electrical conductor, electrical conductors for mounting the chip, the second and a third layer of dielectric material partially covering, on the side of the opening in the metallization of the bottom face of the multilayer integrated circuit, the first layer of dielectric material revealing the electrical conductors for mounting the chip on said first layer of dielectric material.

9. The microwave component as claimed in claim 1, wherein the multilayer integrated circuit comprises, between the bottom face and the top face, a first, a second and a third layer of dielectric material, between the first and the second layers of dielectric material, a first metallic layer comprising at least the electromagnetic coupling electrical conductor, between the second and the third layer of dielectric material at the level of the opening of the metallization of the bottom face of the multilayer integrated circuit, another metallic layer forming a reflective plane for the electromagnetic waves in the contactless microwave port.

10. The microwave component as claimed in claim 1, wherein an electromagnetic coupling electrical conductor and a ground plane of the passive multilayer integrated circuit form a slot antenna favoring the transmission of the working frequency through the contactless microwave port.

11. The microwave component as claimed in claim 1, wherein the coupling electrical conductor is electrically linked to the chip by a microstrip line formed by an electrical conductor of the metallic layer comprising the coupling electrical conductor and the metallized bottom face of the multilayer integrated circuit.

12. The microwave component as claimed in claim 1, wherein the chip (MMIC) and the multilayer integrated circuit are protected by a coating resin sealing the package of the component.

13. The microwave component as claimed in claim 1, wherein the chip (MMIC) is interconnected to the multilayer integrated circuit by electrical conductor wires.

14. The microwave component as claimed in claim 1, wherein the chip (MMIC) is interconnected to the multilayer integrated circuit by metallic pads.
